(19) United States
(12) Patent Application Publication
(10) Pub. No.: US 2024/0405742 A1
(43) Pub. Date: Dec. 5, 2024

(54) ACOUSTIC WAVE DEVICE

(71) Applicant: Murata Manufacturing Co., Ltd., Nagaokakyo-shi (JP)

(72) Inventor: Tetsuya KIMURA, Nagaokakyo-shi (JP)

(21) Appl. No.: 18/804,516

(22) Filed: Aug. 14, 2024

Related U.S. Application Data
(63) Continuation of application No. PCT/JP2023/008893, filed on Mar. 8, 2023.
(60) Provisional application No. 63/317,561, filed on Mar. 8, 2022.

(51) Int. Cl. H03H 9/02; H03H 9/13; H03H 9/17

(52) U.S. Cl. CPC H03H 9/02102; H03H 9/13; H03H 9/17

(57) ABSTRACT

An acoustic wave device includes a piezoelectric layer, and an IDT electrode including first and second electrodes each including electrode fingers extending in a second direction intersecting a first direction and facing each other. The IDT electrode includes first, second, and third groups of electrode fingers continuously arranged in a third direction. The first group of electrode fingers has a largest first width, the second group of electrode fingers has a smallest second width, and the third group of electrode fingers has a third width that is larger than the second width. The third group of electrode fingers, the second group of electrode fingers, the first group of electrode fingers, the second group of electrode fingers, and the third group of electrode fingers are arranged in this order as viewed in the third direction.

### CROSS REFERENCE TO RELATED APPLICATIONS

This application claims the benefit of priority to Provisional Application No. 63/317,561 filed on Mar. 8, 2022 and is a Continuation Application of PCT Application No. PCT/JP2023/008893 filed on Mar. 8, 2023. The entire contents of each application are hereby incorporated herein by reference.

### BACKGROUND OF THE INVENTION

### 1. Field of the Invention

The present disclosure relates to acoustic wave devices.

### 2. Description of the Related Art

Japanese Unexamined Patent Application Publication No. 2012-257019 describes an acoustic wave device.

In the acoustic wave device described in Japanese Unexamined Patent Application Publication No. 2012-257019, widths of a plurality of electrode fingers may be partially different in the acoustic wave device to suppress spurious emissions. If the widths of the electrode fingers differ significantly between a central region and an end portion region, the strength of the entire membrane becomes uneven. In this case, if the thickness of a piezoelectric layer and the film thickness of the electrode fingers are substantially the same, such influence may become more significant, leading to a possibility that the piezoelectric layer may be deflected or destroyed due to distortion caused by heat or stress.

### SUMMARY OF THE INVENTION

Example embodiments of the present invention reduce or prevent deflection of a piezoelectric layer and destruction of the piezoelectric layer while reducing or preventing spurious emissions.

An acoustic wave device according to an example embodiment of the present invention includes a piezoelectric layer including a first main surface and a second main surface opposite to the first main surface and located in a first direction relative to the first main surface, and an IDT electrode including a first electrode including electrode fingers extending in a second direction intersecting the first direction, and a second electrode including electrode fingers extending in the second direction and facing the electrode fingers of the first electrode in a third direction orthogonal or substantially orthogonal to the second direction, the IDT electrode includes a first group of electrode fingers continuously arranged in the third direction, a second group of electrode fingers continuously arranged in the third direction, and a third group of electrode fingers continuously arranged in the third direction, the first group of electrode fingers has a largest first width, the second group of electrode fingers has a smallest second width, and the third group of electrode fingers has a third width that is larger than the second width, and the third group of electrode fingers, the second group of electrode fingers, the first group of electrode fingers, the second group of electrode fingers, and the third group of electrode fingers are arranged in this order as viewed in the third direction.

An acoustic wave device according to an example embodiment of the present invention includes a piezoelectric layer including a first main surface and a second main surface opposite to the first main surface and located in a first direction relative to the first main surface, and an IDT electrode including a first electrode including electrode fingers extending in a second direction intersecting the first direction, and a second electrode including electrode fingers extending in the second direction and facing the electrode fingers of the first electrode in a third direction orthogonal or substantially orthogonal to the second direction, the IDT electrode includes a first group of electrode fingers continuously arranged in the third direction, a second group of electrode fingers continuously arranged in the third direction, and a third group of electrode fingers continuously arranged in the third direction, the first group of electrode fingers has a largest first width, the second group of electrode fingers has a smallest second width, and the third group of electrode fingers has a third width that is smaller than the first width, and the third group of electrode fingers, the first group of electrode fingers, the second group of electrode fingers, the first group of electrode fingers, and the third group of electrode fingers are arranged in this order as viewed in the third direction.

According to example embodiments of the present invention, deflection of the piezoelectric layer and destruction of the piezoelectric layer can be reduced or prevented while reducing or preventing spurious emissions.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a perspective view illustrating an acoustic wave device according to a first example embodiment of the present invention.

FIG. 1B is a plan view illustrating an electrode structure according to the first example embodiment of the present invention.

FIG. 2 is a cross-sectional view of a portion taken along line II-II in FIG. 1A.

FIG. 3A is a schematic cross-sectional view for explaining a Lamb wave propagating through a piezoelectric layer of a comparative example.

FIG. 3B is a schematic cross-sectional view for explaining a bulk wave in a first-order thickness-shear mode propagating through a piezoelectric layer of the first example embodiment of the present invention.

FIG. 4 is a schematic cross-sectional view for explaining an amplitude direction of the bulk wave in the first-order thickness-shear mode propagating through the piezoelectric layer of the first example embodiment of the present invention.

FIG. 5 is an explanatory diagram illustrating an example of resonance characteristics of the acoustic wave device according to the first example embodiment of the present invention.

FIG. 6 is an explanatory diagram illustrating the relationship between d/2p and a fractional band width of a resonator in the acoustic wave device according to the first example embodiment of the present invention, where p is a center-to-center distance or an average distance of the center-to-center distances between adjacent electrodes, and d is an average thickness of the piezoelectric layer.

FIG. 7 is a plan view illustrating an example in which a pair of electrodes are provided in the acoustic wave device according to the first example embodiment of the present invention.

FIG. 8 is a reference diagram illustrating an example of the resonance characteristics of the acoustic wave device according to the first example embodiment of the present invention.

FIG. 9 is an explanatory diagram illustrating the relationship between a fractional band width and a phase rotation amount of a spurious impedance normalized by about 180 degrees as a magnitude of spurious when a large number of acoustic wave resonators are configured in the acoustic wave device according to the first example embodiment of the present invention.

FIG. 10 is an explanatory diagram illustrating a relationship among d/2p, a metallization ratio MR, and a fractional band width.

FIG. 11 is an explanatory diagram illustrating a map of the fractional band width with respect to Euler angles (0°, θ, ψ) of LiNbO₃ when d/p is infinitely close to 0.

FIG. 12 is a partially cutaway perspective view for explaining an acoustic wave device according to an example embodiment of the present invention.

FIG. 13 is a cross-sectional view of a portion taken along line II-II in FIG. 1A according to a modification of the first example embodiment of the present invention.

FIG. 14 is a cross-sectional view illustrating an example of the acoustic wave device according to the first example embodiment of the present invention.

FIG. 15 is a graph illustrating the relationship between the position and width of electrode fingers of the acoustic wave device according to the first example embodiment of the present invention.

FIG. 16 is a graph illustrating the relationship between the position and width of electrode fingers of an acoustic wave device according to a second example embodiment of the present invention.

FIG. 17 is a graph illustrating the relationship between the position and width of electrode fingers of an acoustic wave device according to a modification of the second example embodiment of the present invention.

### DETAILED DESCRIPTION OF THE EXAMPLE EMBODIMENTS

Hereinafter, example embodiments of the present invention will be described in detail with reference to the drawings. The present invention is not limited to the example embodiments. Each example embodiment described in the present disclosure is an example, and in modifications in which partial replacement or combination of configurations is possible between different example embodiments, or in the second and subsequent example embodiments, description of matters common to the first example embodiment will be omitted, and only different points will be described. In particular, the same or substantially the same advantageous effects obtained by the same configurations will not be described in each example embodiment.

### First Example Embodiment

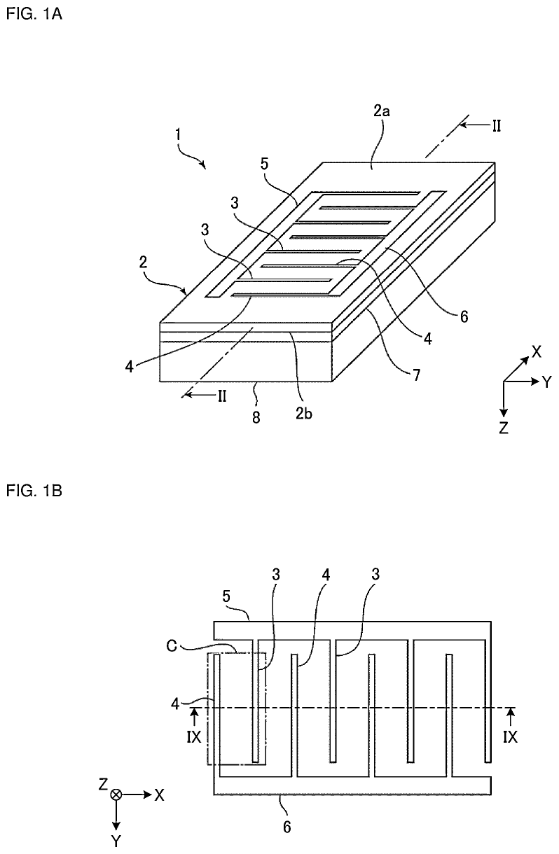

FIG. 1A is a perspective view illustrating an acoustic wave device according to a first example embodiment of the present invention. FIG. 1B is a plan view illustrating an electrode structure according to the first example embodiment.

An acoustic wave device 1 of the first example embodiment includes a piezoelectric layer 2 made of, for example, LiNbO₃. The piezoelectric layer 2 may be made of LiTaO₃, for example. The cut-angle of LiNbO₃ or LiTaO₃ is a Z-cut in the first example embodiment. The cut-angle of LiNbO₃ or LiTaO₃ may be a rotated Y-cut or X-cut. For example, the propagation directions of Y propagation and X propagation about ±30° are preferable.

The thickness of the piezoelectric layer 2 is not particularly limited, but is, for example, preferably more than or equal to about 50 nm and less than or equal to about 1000 nm in order to effectively excite the first-order thickness-shear mode.

The piezoelectric layer 2 includes a first main surface 2a and a second main surface 2b facing each other in a Z direction. Electrode fingers 3 and electrode fingers 4 are provided on the first main surface 2a.

Here, the electrode finger 3 is an example of a “first electrode finger” and the electrode finger 4 is an example of a “second electrode finger”. In FIGS. 1A and 1B, a plurality of the electrode fingers 3 are a plurality of “first electrode fingers” connected to a first busbar electrode 5. A plurality of the electrode fingers 4 are a plurality of “second electrode fingers” connected to a second busbar electrode 6. The plurality of electrode fingers 3 and the plurality of electrode fingers 4 are interdigitated with each other. This forms an interdigital transducer (IDT) electrode including the electrode fingers 3, the electrode fingers 4, the first busbar electrode 5, and the second busbar electrode 6.

The electrode finger 3 and the electrode finger 4 have a rectangular or substantially rectangular shape and have a length direction. In a direction orthogonal or substantially orthogonal to the length direction, the electrode finger 3 and the electrode finger 4 adjacent to the electrode finger 3 face each other. The length direction of the electrode fingers 3 and 4 and the direction orthogonal or substantially orthogonal to the length direction of the electrode fingers 3 and 4 each are a direction intersecting a thickness direction of the piezoelectric layer 2. Therefore, it can also be said that the electrode finger 3 and the electrode finger 4 adjacent to the electrode finger 3 face each other in a direction intersecting the thickness direction of the piezoelectric layer 2. In the following description, the thickness direction of the piezoelectric layer 2 may be referred to as a Z direction (or a first direction), the length direction of the electrode finger 3 and the electrode finger 4 may be referred to as a Y direction (or a second direction), and the direction orthogonal to the length direction of the electrode finger 3 and the electrode finger 4 may be referred to as an X direction (or a third direction).

Further, the length direction of the electrode finger 3 and the electrode finger 4 may be replaced with the direction orthogonal or substantially orthogonal to the length direction of the electrode finger 3 and the electrode finger 4 illustrated in FIGS. 1A and 1B. That is, the electrode finger 3 and the electrode finger 4 may extend in the direction in which the first busbar electrode 5 and the second busbar electrode 6 extend in FIGS. 1A and 1B. In this case, the first busbar electrode 5 and the second busbar electrode 6 extend in the direction in which the electrode finger 3 and the electrode finger 4 extend in FIGS. 1A and 1B. A plurality of pairs of structures in which the electrode finger 3 connected to one potential and the electrode finger 4 connected to the other potential are adjacent to each other are provided in the direction orthogonal to the length direction of the electrode finger 3 and the electrode finger 4 described above.

Here, the electrode finger 3 and the electrode finger 4 being adjacent to each other refers not to a case where the electrode finger 3 and the electrode finger 4 are arranged so as to be in direct contact with each other but to a case where the electrode finger 3 and the electrode finger 4 are arranged with an interval therebetween. In addition, when the electrode finger 3 and the electrode finger 4 are adjacent to each other, an electrode connected to a hot electrode or a ground electrode, including the other electrode fingers 3 and 4, is not arranged between the electrode finger 3 and the electrode finger 4. The number of pairs need not be integer pairs, but may be 1.5 pairs, 2.5 pairs, or the like.

The center-to-center distance between the electrode finger 3 and the electrode finger 4, that is, the pitch is, for example, preferably in the range of more than or equal to about 1 μm and less than or equal to about 10 μm. In addition, the center-to-center distance between the electrode finger 3 and the electrode finger 4 is a distance connecting the center of the width dimension of the electrode finger 3 in the direction orthogonal or substantially orthogonal to the length direction of the electrode finger 3 and the center of the width dimension of the electrode finger 4 in the direction orthogonal or substantially orthogonal to the length direction of the electrode finger 4.

Further, in a case where at least one of the electrode finger 3 and the electrode finger 4 defines a plurality of pairs (when the electrode finger 3 and the electrode finger 4 defines a pair of electrode sets, there are 1.5 or more pairs of electrode sets), the center-to-center distance between the electrode finger 3 and the electrode finger 4 refers to the average value of the center-to-center distances between the respective adjacent electrode fingers 3 and 4 of the 1.5 or more pairs of electrode fingers 3 and 4.

In addition, the width of the electrode fingers 3 and 4, that is, the dimension of the electrode fingers 3 and 4 in their facing direction, is, for example, preferably in the range of more than or equal to about 150 nm and less than or equal to about 1000 nm. The center-to-center distance between the electrode finger 3 and the electrode finger 4 is a distance connecting the center of the dimension (width dimension) of the electrode finger 3 in the direction orthogonal or substantially orthogonal to the length direction of the electrode finger 3 and the center of the dimension (width dimension) of the electrode finger 4 in the direction orthogonal or substantially orthogonal to the length direction of the electrode finger 4.

In the first example embodiment, since the Z-cut piezoelectric layer is used, the direction orthogonal or substantially orthogonal to the length direction of the electrode fingers 3 and 4 is a direction orthogonal or substantially orthogonal to the polarization direction of the piezoelectric layer 2. This does not apply when a piezoelectric body of another cut-angle is used as the piezoelectric layer 2. Here, “orthogonal” is not limited to strictly orthogonal but may be substantially orthogonal (an angle between the direction orthogonal to the length direction of the electrode finger 3 and the electrode finger 4 and the polarization direction is, for example, about 90°±10°).

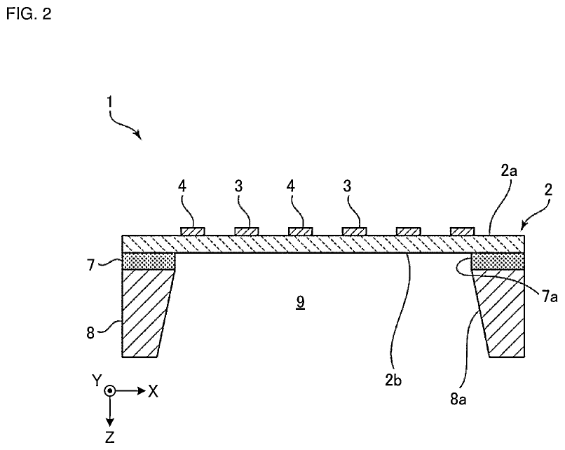

A support substrate 8 is laminated on the second main surface 2b side of the piezoelectric layer 2 with an intermediate layer 7 interposed therebetween. The intermediate layer 7 and the support substrate 8 have a frame shape and include cavities 7a and 8a as illustrated in FIG. 2. Thus, a space portion (air gap) 9 is provided.

The space portion 9 is provided so as not to interfere with the vibration of an excitation region C of the piezoelectric layer 2. Therefore, the support substrate 8 is laminated on the second main surface 2b with the intermediate layer 7 interposed therebetween at a position not overlapping a portion where at least a pair of electrode fingers 3 and 4 are provided. The intermediate layer 7 need not be provided. Therefore, the support substrate 8 can be directly or indirectly laminated on the second main surface 2b of the piezoelectric layer 2.

The intermediate layer 7 is made of, for example, silicon oxide. However, the intermediate layer 7 can be made of an appropriate insulating material such as, for example, silicon oxynitride or alumina in addition to silicon oxide.

The support substrate 8 is made of, for example, Si. The plane orientation of the surface of Si on the piezoelectric layer 2 side may be (100), (110), or (111). Preferably, high-resistance Si having a resistivity of, for example, more than or equal to about 4 kΩ is preferable. However, the support substrate 8 can also be made using an appropriate insulating material or semiconductor material. Examples of the material of the support substrate 8 include piezoelectric bodies such as aluminum oxide, lithium tantalate, lithium niobate, and quartz crystal, various ceramics such as alumina, magnesia, sapphire, silicon nitride, aluminum nitride, silicon carbide, zirconia, cordierite, mullite, steatite, and forsterite, dielectrics such as diamond and glass, and semiconductors such as gallium nitride, and the like.

The plurality of electrode fingers 3 and 4, the first busbar electrode 5, and the second busbar electrode 6 are made of an appropriate metal or alloy such as Al or an AlCu alloy, for example. In the first example embodiment, for example, the electrode fingers 3 and 4, the first busbar electrode 5, and the second busbar electrode 6 have a structure in which an Al film is laminated on a Ti film. A material other than the Ti film may be used for a close contact layer.

At the time of driving, an AC voltage is applied between the plurality of electrode fingers 3 and the plurality of electrode fingers 4. More specifically, an AC voltage is applied between the first busbar electrode 5 and the second busbar electrode 6. As a result, it is possible to obtain resonance characteristics using a bulk wave in the first-order thickness-shear mode excited in the piezoelectric layer 2.

In the acoustic wave device 1, for example, d/p is less than or equal to about 0.5, where d is the thickness of the piezoelectric layer 2, and p is the center-to-center distance between any adjacent electrode fingers 3 and 4 of the plurality of pairs of electrode fingers 3 and 4. Therefore, the bulk wave in the first-order thickness-shear mode is effectively excited, and good resonance characteristics can be obtained. More preferably, for example, d/p is less than or equal to about 0.24, in which case even better resonance characteristics can be obtained.

In a case where at least one of the electrode finger 3 and the electrode finger 4 defines a plurality of pairs as in the first example embodiment, that is, in a case where, when the electrode finger 3 and the electrode finger 4 define a pair of electrode sets, the electrode finger 3 and the electrode finger 4 provide 1.5 or more pairs, the center-to-center distance between the adjacent electrode fingers 3 and 4 is an average distance of the center-to-center distances between the respective adjacent electrode fingers 3 and 4.

Since the acoustic wave device 1 according to the first example embodiment has the configuration described above, even when the number of pairs of the electrode finger 3 and the electrode finger 4 is reduced in an attempt to achieve a reduction in size, Q value is not easily reduced. This is because the resonator does not require reflectors on both sides and has a small propagation loss. In addition, the reason why the above reflector is not required is that the bulk wave in the first-order thickness-shear mode is used.

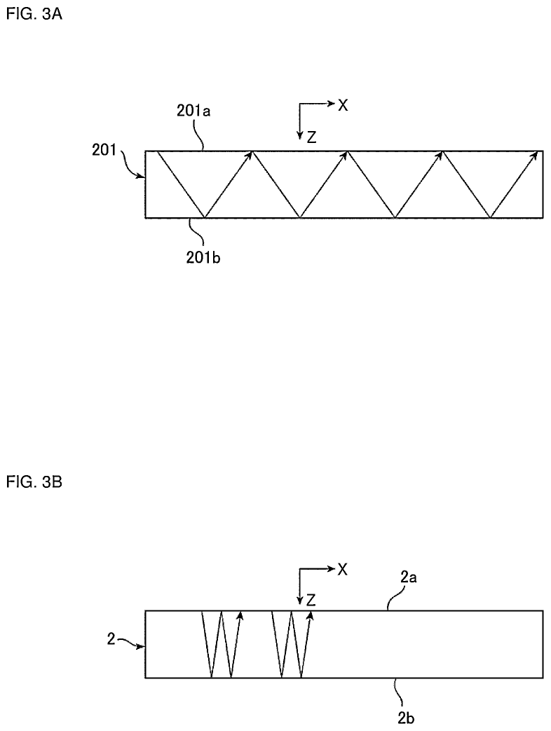

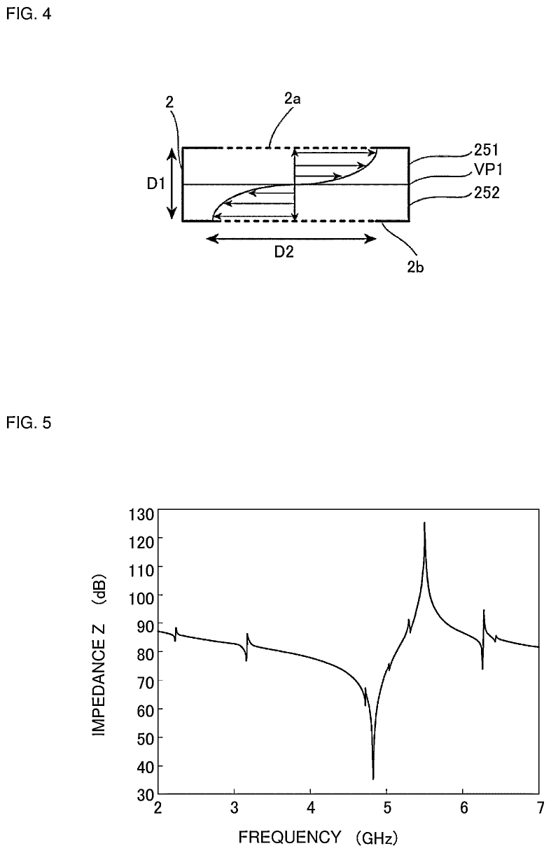

FIG. 3A is a schematic cross-sectional view for explaining a Lamb wave propagating through a piezoelectric layer of a comparative example. FIG. 3B is a schematic cross-sectional view for explaining a bulk wave in the first-order thickness-shear mode propagating through a piezoelectric layer of the first example embodiment. FIG. 4 is a schematic cross-sectional view for explaining an amplitude direction of the bulk wave in the first-order thickness-shear mode propagating through the piezoelectric layer of the first example embodiment.

In FIG. 3A, an acoustic wave device as described in Japanese Unexamined Patent Application Publication No. 2012-257019 is illustrated, and a Lamb wave propagates through a piezoelectric layer. As illustrated in FIG. 3A, a wave propagates through a piezoelectric layer 201 as indicated by arrows. Here, the piezoelectric layer 201 includes a first main surface 201a and a second main surface 201b, and the thickness direction connecting the first main surface 201a and the second main surface 201b is the Z direction. The X direction is a direction in which electrode fingers 3 and 4 of an IDT electrode are arranged. As illustrated in FIG. 3A, the Lamb wave propagates in the X direction. Although the piezoelectric layer 201 vibrates as a whole because of the plate wave, since the wave propagates in the X direction, reflectors are arranged on both sides to obtain resonance characteristics. Therefore, a propagation loss of waves occurs, and the Q value decreases when the size is reduced, that is, when the number of pairs of electrode fingers 3 and 4 is reduced.

On the other hand, as illustrated in FIG. 3B, in the acoustic wave device of the first example embodiment, since the vibration displacement is in the thickness-shear direction, the wave substantially propagates in the direction connecting the first main surface 2a and the second main surface 2b of the piezoelectric layer 2, that is, the Z direction, and resonates. Specifically, the X direction component of the wave is significantly smaller than the Z direction component. Since resonance characteristics are obtained by the propagation of the wave in the Z direction, a reflector is not required. Therefore, propagation loss does not occur when the wave propagates to the reflector. Therefore, even when the number of pairs of electrodes consisting of the electrode finger 3 and the electrode finger 4 is reduced in an attempt to reduce the size, the Q value is not easily reduced.

As illustrated in FIG. 4, the amplitude direction of the bulk wave in the first-order thickness-shear mode in a first region 251 included in the excitation region C (see FIG. 1B) of the piezoelectric layer 2 is the opposite in a second region 252 included in the excitation region C. FIG. 4 schematically illustrates a bulk wave when a voltage is applied between the electrode finger 3 and the electrode finger 4 so that the electrode finger 4 has a higher potential than the electrode finger 3. The first region 251 is a region between the first main surface 2a and a virtual plane VP1 that is orthogonal or substantially orthogonal to the thickness direction of the piezoelectric layer 2 and divides the piezoelectric layer 2 into two parts in the excitation region C. The second region 252 is a region between the virtual plane VP1 and the second main surface 2b in the excitation region C.

In the acoustic wave device 1, at least a pair of electrodes including the electrode finger 3 and the electrode finger 4 are arranged. However, since waves are not propagated in the X direction, the plurality of pairs of electrodes including the electrode finger 3 and the electrode finger 4 are not always necessary. That is, only at least a pair of electrodes may be provided.

For example, the electrode finger 3 is an electrode connected to the hot potential, and the electrode finger 4 is an electrode connected to the ground potential. However, the electrode finger 3 may be connected to the ground potential and the electrode finger 4 may be connected to the hot potential. In the first example embodiment, as described above, at least a pair of electrodes are the electrode connected to the hot potential or the electrode connected to the ground potential, and a floating electrode is not provided.

FIG. 5 is an explanatory diagram illustrating an example of resonance characteristics of the acoustic wave device according to the first example embodiment. The design parameters of the acoustic wave device 1 having the resonance characteristics illustrated in FIG. 5 are as follows.
Piezoelectric layer 2: LiNbO₃ with Euler angles (0°, 0°, 90°)
Thickness of piezoelectric layer 2: about 400 nm
Length of excitation region C (see FIG. 1B): about 40 μm
Number of pairs of electrodes consisting of electrode finger 3 and electrode finger 4: 21 pairs
Center-to-center distance (pitch) between electrode finger 3 and electrode finger 4: about 3 μm
Width of electrode fingers 3 and 4: about 500 nm
d/p: about 0.133
Intermediate layer 7: silicon oxide film with thickness of about 1 μm
Support substrate 8: Si

The excitation region C (see FIG. 1B) is a region in which the electrode finger 3 and the electrode finger 4 overlap as seen in the X direction orthogonal or substantially orthogonal to the length direction of the electrode fingers 3 and 4. The length of the excitation region C is a dimension of the excitation region C along the length direction of the electrode fingers 3 and 4. Here, the excitation region C is an example of an “intersection region”.

In the first example embodiment, the center-to-center distances of the electrode pairs including the electrode fingers 3 and the electrode fingers 4 are all equal or substantially equal in the plurality of pairs. That is, the electrode fingers 3 and the electrode fingers 4 are arranged with equal or substantially equal pitches.

As is clear from FIG. 5, good resonance characteristics with the fractional band width of about, about 12.5% are obtained even though no reflector is provided.

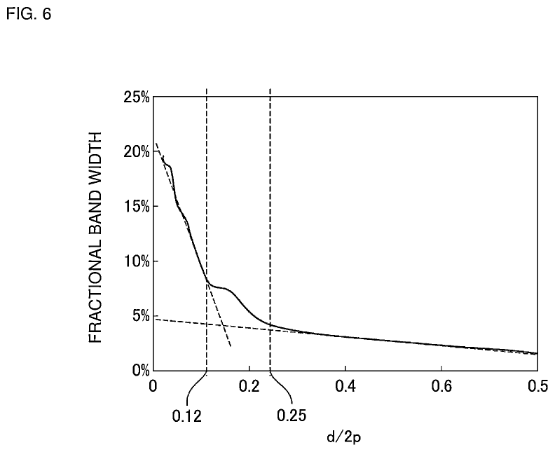

In the first example embodiment about, d/p is less than or equal to about 0.5, more preferably less than or equal to about 0.24, where d is the thickness of the piezoelectric layer 2 and p is the center-to-center distance between the electrode finger 3 and the electrode finger 4. This will be described with reference to FIG. 6.

A plurality of acoustic wave devices are obtained in the same or substantially the same manner as the acoustic wave device having the resonance characteristics illustrated in FIG. 5, except that d/2p is changed. FIG. 6 is an explanatory diagram illustrating the relationship between d/2p and a fractional band width of a resonator in the acoustic wave device of the first example embodiment, where p is the center-to-center distance or the average distance of the center-to-center distances between adjacent electrodes, and d is the average thickness of the piezoelectric layer 2.

As illustrated in FIG. 6, for example, when d/2p exceeds about 0.25, that is, d/p>about 0.5, the fractional band width is less than about 5% even when d/p is adjusted. On the other hand, when d/2p≤about 0.25, that is, d/p≥about 0.5, the fractional band width can be more than or equal to about 5% by changing d/p within the range, that is, the resonator having a high coupling coefficient can be provided. In addition, when d/2p is less than or equal to about 0.12, that is, d/p is less than or equal to about 0.24, the fractional band width can be increased to more than or equal to about 7%. In addition, when d/p is adjusted within this range, a resonator having a wider fractional band width can be obtained, and a resonator having a higher coupling coefficient can be realized. Therefore, it is understood that by setting d/p to less than or equal to about 0.5, a resonator having a high coupling coefficient using the bulk wave in the first-order thickness-shear mode described above can be provided.

The at least one pair of electrodes may be a pair of electrodes, and in the case of one pair of electrodes, p is the center-to-center distance between the adjacent electrode fingers 3 and 4. Further, in the case of 1.5 or more pairs of electrodes, p may be the average distance of the center-to-center distances between the adjacent electrode fingers 3 and 4.

For the piezoelectric layer 2, when the piezoelectric layer 2 has variations in thickness d, a value obtained by averaging the thicknesses may be used.

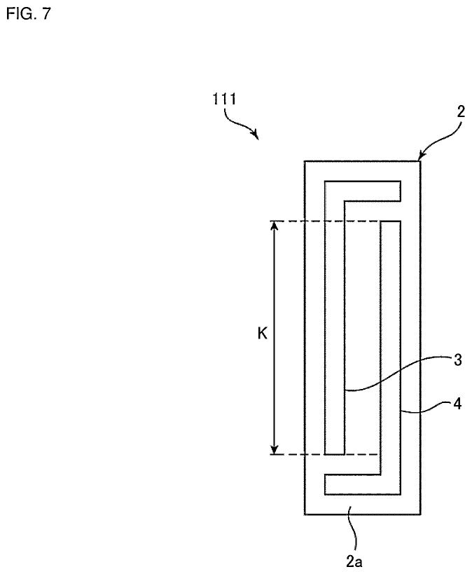

FIG. 7 is a plan view illustrating an example in which a pair of electrodes are provided in the acoustic wave device of the first example embodiment. In an acoustic wave device 101, a pair of electrodes including the electrode finger 3 and the electrode finger 4 are provided on the first main surface 2a of the piezoelectric layer 2. K in FIG. 7 is an intersecting width. As described above, in the acoustic wave device of the present disclosure, the number of pairs of electrodes may be one. Also in this case about, when d/p is less than or equal to about 0.5, the bulk wave in the first-order thickness-shear mode can be effectively excited.

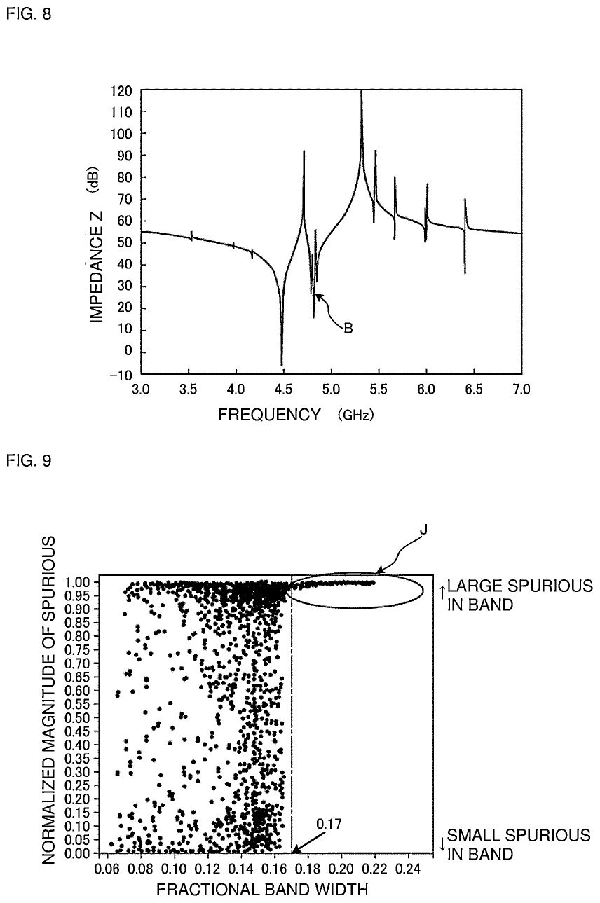

In the acoustic wave device 1, it is preferable that the metallization ratio MR of any adjacent electrode fingers 3 and electrode fingers 4 of the plurality of electrode fingers 3 and electrode fingers 4 with respect to the excitation region C, which is a region where the adjacent electrode fingers 3 and electrode fingers 4 overlap when viewed in the direction in which they face each other, satisfies MR≤about 1.75 (d/p)+0.075. In that case, it is possible to effectively reduce spurious emissions. This will be described with reference to FIGS. 8 and 9.

FIG. 8 is a reference diagram illustrating an example of the resonance characteristics of the acoustic wave device according to the first example embodiment. A spurious emission indicated by an arrow B appears between a resonant frequency and an anti-resonant frequency. For example, d/p=about 0.08 and the Euler angles of LiNbO₃ are (0°, 0°, 90°). The metallization ratio MR is about 0.35.

The metallization ratio MR will be described with reference to FIG. 1B. In the electrode structure of FIG. 1B, when focusing on a pair of electrode fingers 3 and 4, it is assumed that only this pair of electrode fingers 3 and 4 is provided. In this case, a portion surrounded by a dashed-dotted line is the excitation region C. When the electrode finger 3 and the electrode finger 4 are viewed in the direction orthogonal or substantially orthogonal to the length direction of the electrode finger 3 and the electrode finger 4, that is, in their facing direction, the excitation region C is a region of the electrode finger 3 that overlaps the electrode finger 4, a region of the electrode finger 4 that overlaps the electrode finger 3, and a region between the electrode finger 3 and the electrode finger 4 where the electrode finger 3 and the electrode finger 4 overlap each other. An area of the electrode fingers 3 and 4 in the excitation region C with respect to the area of the excitation region C is the metallization ratio MR. That is, the metallization ratio MR is the ratio of the area of the metallization portion to the area of the excitation region C.

When a plurality of pairs of electrode fingers 3 and 4 are provided, the ratio of the metallization portion included in the entire excitation region C to the total area of the excitation region C may be MR.

FIG. 9 is an explanatory diagram illustrating a relationship between a fractional band width and a phase rotation amount of the spurious impedance normalized by about 180 degrees as the magnitude of the spurious when a large number of acoustic wave resonators are configured in the acoustic wave device according to the first example embodiment. The fractional band width is adjusted by changing the film thickness of the piezoelectric layer 2 and the dimensions of the electrode fingers 3 and 4. FIG. 9 illustrates the results when a Z-cut LiNbO₃ piezoelectric layer 2 is used, but the same tendency is obtained also when piezoelectric layers 2 with other cut-angles are used.

In a region surrounded by an ellipse J in FIG. 9, the spurious emission is as large as about 1.0. As is clear from FIG. 9, when the fractional band width exceeds about 0.17, that is, exceeds about 17%, a large spurious emission with a spurious level of more than or equal to about 1 appears in a pass band even when the parameters defining the fractional band width are changed. That is, as in the resonance characteristics illustrated in FIG. 8, a large spurious emission indicated by the arrow B appears within the band. Therefore, for example, the fractional band width is preferably less than or equal to about 178. In this case, the spurious can be reduced by adjusting the film thickness of the piezoelectric layer 2, the dimensions of the electrode fingers 3 and 4, or the like.

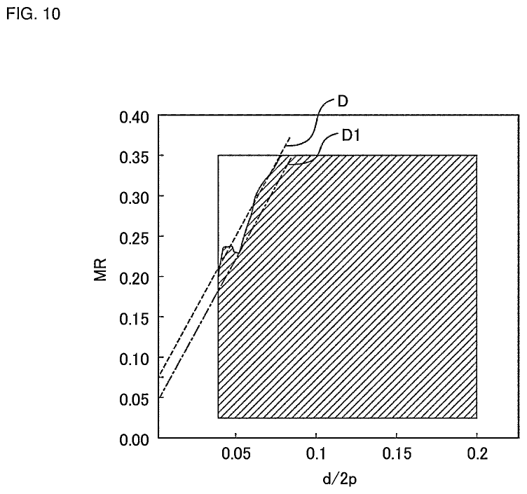

FIG. 10 is an explanatory diagram illustrating a relationship among d/2p, the metallization ratio MR, and the fractional band width. In the acoustic wave device 1 according to the first example embodiment, various acoustic wave devices 1 having different values of d/2p and different values of MR are provided, and the fractional band width is measured. A hatched portion to the right of a dashed line D illustrated in FIG. 10 is a region where the fractional band width is less than or equal to about 17%. The boundary between the hatched region and the non-hatched region is represented by MR=about 3.5 (d/2p)+0.075. That is, MR=about 1.75 (d/p)+0.075. Therefore, for example, MR≤ about 1.75 (d/p)+0.075 is preferably satisfied. In this case, the fractional band width is easily set to less than or equal to about 17%. More preferably, it is the region in FIG. 10 to the right of a dashed-dotted line D1 indicating MR=about 3.5 (d/2p)+0.05. That is, for example, when MR≤about 1.75 (d/p)+0.05, the fractional band width can be reliably set to less than or equal to about 17%.

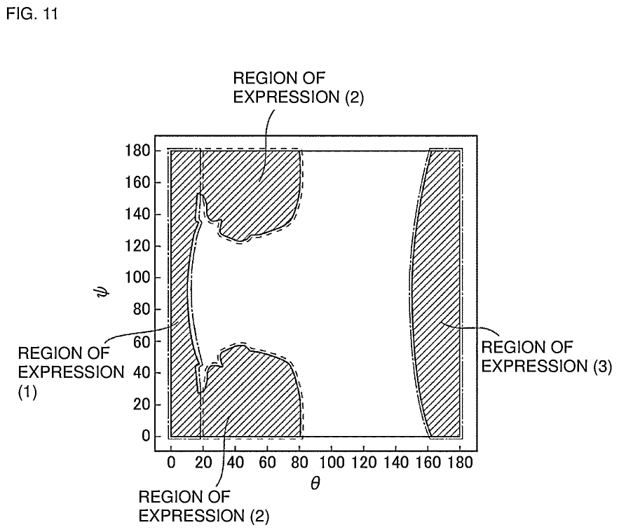

FIG. 11 is a diagram illustrating a map of the fractional band width with respect to the Euler angles (0°, θ, ψ) of LiNbO₃ when d/p is infinitely close to 0. A hatched portion in FIG. 11 is a region where the fractional band width of at least more than or equal to 5% is obtained, and the range of the region is approximated by the following Expressions (1), (2), and (3).

(0°±10°,0° to 20°, any ψ) Expression (1)

(0°±10°,20° to 80°,0° to 60°(1−(θ−50)²/900)^{1/2}) or (0°±10°,20° to 80°,[180°−60°(1−(θ−50)²/900)^{1/2}] to 180°) Expression (2)

(0°±10°,[180°−30°(1−(ψ−90)²/8100)^{1/2}] to 180°, any ψ) Expression (3)

Therefore, in the case of the Euler angle range of Expression (1), Expression (2), or Expression (3), the fractional band width can be sufficiently widened, which is preferable.

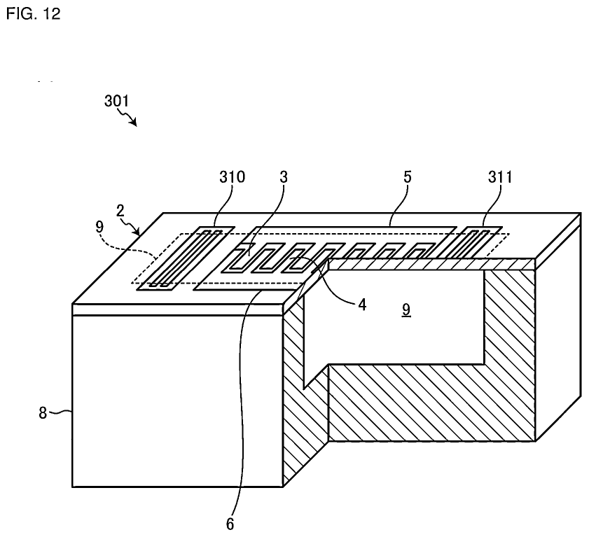

FIG. 12 is a partially cutaway perspective view for explaining an acoustic wave device according to an example embodiment of the present invention. In FIG. 12, an outer periphery of the space portion 9 is indicated by a dashed line. The acoustic wave device of the present invention may use plate waves. In this case, as illustrated in FIG. 12, an acoustic wave device 301 includes reflectors 310 and 311. The reflectors 310 and 311 are provided on both sides of the electrode fingers 3 and 4 of the piezoelectric layer 2 in the acoustic wave propagation direction. In the acoustic wave device 301, a Lamb wave as a plate wave is excited by applying an AC electric field to the electrode fingers 3 and 4 above the space portion 9. Since the reflectors 310 and 311 are provided on both sides, resonance characteristics due to the Lamb wave as a plate wave can be obtained.

As described above, in the acoustic wave devices 1 and 101, a first-order thickness shear mode bulk wave is used. Further, in the acoustic wave devices 1 and 101, the first electrode finger 3 and the second electrode finger 4 are adjacent electrodes, and d/p is less than or equal to 0.5, where d is the thickness of the piezoelectric layer 2 and p is the center-to-center distance between the first electrode finger 3 and the second electrode finger 4. As a result, the Q value can be increased even when the size of the acoustic wave device is reduced.

In the acoustic wave devices 1 and 101, the piezoelectric layer 2 is made of, for example, lithium niobate or lithium tantalate. The first main surface 2a or the second main surface 2b of the piezoelectric layer 2 include the first electrode finger 3 and the second electrode finger 4 facing each other in a direction intersecting the thickness direction of the piezoelectric layer 2, and the first electrode finger 3 and the second electrode finger 4 are preferably covered with a protective film.

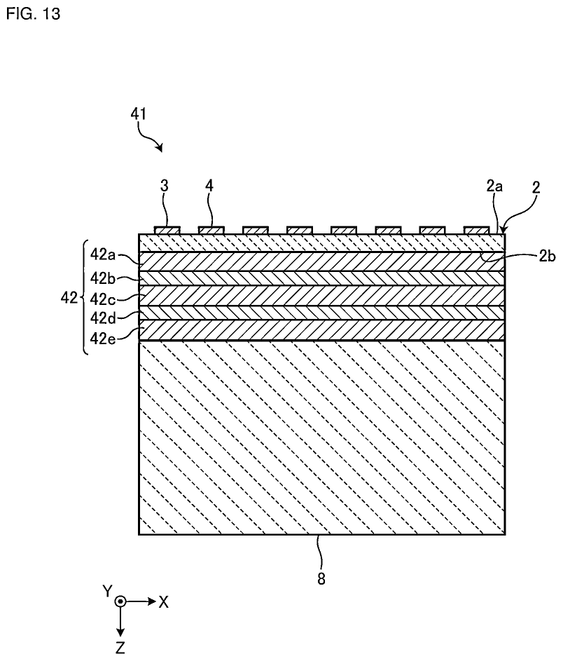

FIG. 13 is a cross-sectional view of a portion taken along line II-II in FIG. 1A according to a modification of the first example embodiment. In an acoustic wave device 41, an acoustic multilayer film 42 is laminated on a second main surface 2b of a piezoelectric layer 2. The acoustic multilayer film 42 has a laminated structure including low acoustic impedance layers 42a, 42c, and 42e having a relatively low acoustic impedance and high acoustic impedance layers 42b and 42d having a relatively high acoustic impedance. Using the acoustic multilayer film 42 makes it possible to confine a bulk wave in the first-order thickness-shear mode within the piezoelectric layer 2, without using the space portion 9 in the acoustic wave device 1. In the acoustic wave device 41, the resonance characteristics based on the bulk wave in the first-order thickness-shear mode can be obtained by setting the above d/p to less than or equal to about 0.5, for example. In the acoustic multilayer film 42, the number of the low acoustic impedance layers 42a, 42c, and 42e and the high acoustic impedance layers 42b and 42d is not particularly limited. At least one of the high acoustic impedance layers 42b and 42d need only be located farther from the piezoelectric layer 2 than the low acoustic impedance layers 42a, 42c, and 42e.

The low acoustic impedance layers 42a, 42c, and 42e and the high acoustic impedance layers 42b and 42d can be made of any suitable material as long as the acoustic impedance relationship is satisfied. For example, the low acoustic impedance layers 42a, 42c, and 42e can be made of silicon oxide, silicon oxynitride or the like. The high acoustic impedance layers 42b and 42d can be made of alumina, silicon nitride, metal or the like.

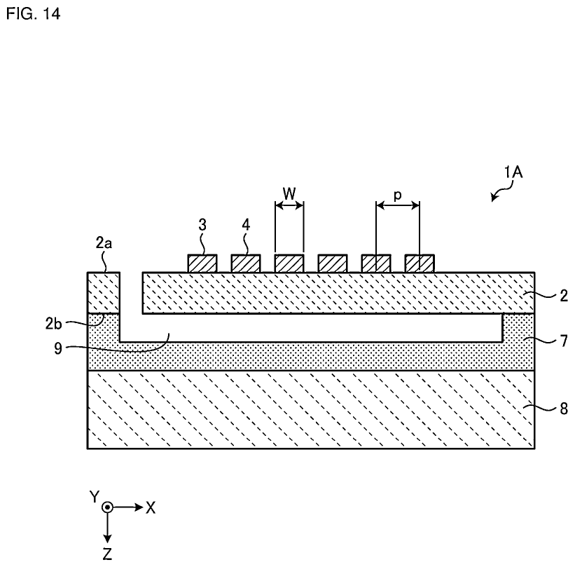

FIG. 14 is a cross-sectional view showing an example of the acoustic wave device according to the first example embodiment. An acoustic wave device 1A illustrated in FIG. 14 includes a piezoelectric layer 2, an intermediate layer 7, a support member, and an IDT electrode. The IDT electrode includes a first electrode including a plurality of electrode fingers 3, and a second electrode including an electrode finger 4 facing any one of the electrode fingers 3 of the first electrode in the X direction. As illustrated in FIG. 14, the electrode fingers 3 and 4 are arranged in the X direction. In the example of FIG. 14, the intermediate layer 7 has a space portion 9, but the present disclosure is not limited thereto. The support substrate 8 may include the space portion 9 as in FIGS. 1B and 12 described above, or the acoustic multilayer film 42 may be provided instead of the intermediate layer 7 as in FIG. 13.

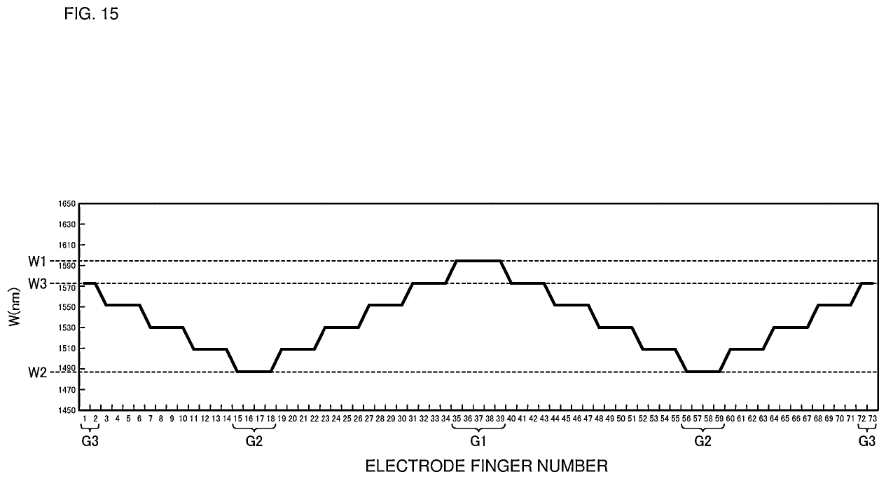

FIG. 15 is a graph illustrating the relationship between the position and width of the electrode fingers of the acoustic wave device according to the first example embodiment. As shown in FIG. 15, the IDT electrode includes a first group G1 of electrode fingers, a second group G2 of electrode fingers, and a third group G3 of electrode fingers.

Here, the width of the electrode fingers is the length in a direction perpendicular or substantially perpendicular to the length direction of the electrode fingers 3 and 4, that is, the length in the X direction, and may be hereinafter referred to as a width W.

In the graph of FIG. 15, the electrode finger numbers illustrated on the horizontal axis refer to numbers assigned to the electrode fingers sequentially in a positive direction of the X direction with No. 1 assigned to the electrode finger that is farthest in a negative direction of the X direction among the plurality of electrode fingers 3 and 4. Therefore, the electrode finger with the number k, where k is a natural number, refers to the k-th electrode finger counting from the electrode finger that is farthest in the negative direction of the X direction. In other words, the electrode finger number can be said to be a parameter indicating the position of one of the plurality of electrode fingers 3 and 4 in the X direction.

The group of electrode fingers refers to a group of the electrode fingers 3 and 4 that are lined up consecutively in the X direction and have the same or substantially the same electrode finger width W, among the plurality of electrode fingers 3 and 4. More specifically, in the group of electrode fingers, there is no electrode finger with a different width W between one electrode finger and another electrode finger, and the electrode finger at the end of the group of electrode fingers in the X direction is the electrode finger adjacent in the X direction to the electrode finger with the different width W, or the electrode finger at the end in the X direction of the IDT electrode of a resonator including the electrode finger at the end.

The first group G1 is a group of electrode fingers having the largest width W among the plurality of electrode fingers 3 and 4. The second group G2 is a group of electrode fingers having the smallest width W among the plurality of electrode fingers 3 and 4. The third group G3 is a group of electrode fingers having a width W larger than that of the second group G2 of electrode fingers among the plurality of electrode fingers 3 and 4. More specifically, the third group G3 refers to a group of electrode fingers located in the outermost side portion among the groups of electrode fingers 3 and 4 having the width W larger than the width W of the electrode fingers included in the second group G2 and smaller than the width W of the electrode fingers included in the first group G1. In the following description, the first group G1 of electrode fingers, the second group G2 of electrode fingers, and the third group G3 of electrode fingers refer to the electrode fingers included in the first group G1, the second group G2, and the third group G3, respectively. A first width W1, a second width W2, and a third width W3 refer to the widths W of the electrode fingers in the first group G1, the second group G2, and the third group G3, respectively.

As illustrated in FIG. 15, in the IDT electrode according to the first example embodiment, the third group G3 of electrode fingers, the second group G2 of electrode fingers, the first group G1 of electrode fingers, the second group G2 of electrode fingers, and the third group G3 of electrode fingers are arranged in this order in ascending order of the electrode finger numbers. In other words, in the IDT electrode according to the first example embodiment, the second group G2 of electrode fingers having the smallest width W are located on the outer side, in the X direction, of the first group G1 of electrode fingers having the largest width W, and the third group G3 of electrode fingers having a width W larger than that of the second group G2 of electrode fingers are located on the side of the second group G2 of electrode fingers, in the X direction, opposite to the side where the first group G1 of electrode fingers are located.

With such a configuration, the plurality of electrode fingers 3 and 4 include electrode fingers having different widths W, thus making it possible to reduce or prevent spurious emissions that occur at a specific frequency due to the concentration of the displacement mode of the electrode fingers. On the other hand, the strength of the piezoelectric layer 2 in the portion where the second group G2 of electrode fingers is located on the outside of the first group G1 of electrode fingers in the X direction is smaller than that of the piezoelectric layer 2 in the portion where the first group G1 of electrode fingers is located. However, the strength of the piezoelectric layer 2 in the portion where the third group G3 of electrode fingers is located on the outside of the second group G2 of electrode fingers in the X direction is greater than that of the piezoelectric layer 2 in the portion where the second group G2 of electrode fingers is located. This makes it possible, even if heat or stress is applied, to reduce or prevent partial deflection of the piezoelectric layer 2 where the electrode fingers at the ends of the plurality of electrode fingers 3 and 4 in the X direction are located, or damage to the piezoelectric layer 2 due to cracks. The deflection of the piezoelectric layer 2 and destruction of the piezoelectric layer 2 can thus be reduced or prevented while reducing or preventing the spurious emissions.

The second width W2 is, for example, preferably more than or equal to about 87% and less than or equal to about 93% of the first width W1. The third width W3 is, for example, preferably more than or equal to about 94% and less than or equal to about 99% of the first width W1. In the example of FIG. 15, the second width W2 is, for example, about 93% of the first width W1, and the third width W3 is, for example, about 98% of the first width W1. This makes it possible to reduce or prevent the deflection of the piezoelectric layer 2 and the destruction of the piezoelectric layer 2 while reducing or preventing the spurious emissions.

In the first example embodiment, a center-to-center distance p1 between adjacent electrode fingers in the first group G1 of electrode fingers, a center-to-center distance p2 between adjacent electrode fingers in the second group G2 of electrode fingers, and a center-to-center distance p3 between adjacent electrode fingers in the third group G3 of electrode fingers are equal or substantially equal. In the example of FIG. 14, the center-to-center distances p between adjacent electrode fingers in the plurality of electrode fingers 3 and 4 are all equal or substantially equal, and p can be set to about 3.5 μm, for example.

Although an example of the acoustic wave device according to the first example embodiment has been described above, the acoustic wave device according to the first example embodiment is not limited to the acoustic wave device 1A illustrated in FIG. 14.

For example, the center-to-center distance p1 between adjacent electrode fingers in the first group G1 of electrode fingers, the center-to-center distance p2 between adjacent electrode fingers in the second group G2 of electrode fingers, and the center-to-center distance p3 between adjacent electrode fingers in the third group G3 of electrode fingers may be different from each other. Specifically, for example, when p1 is about 3.5 μm, the absolute value of the difference between p2 and p1 may be more than or equal to about 0.5% and less than or equal to about 20% of p1, and the absolute value of the difference between p3 and p1 may be more than or equal to about 0.5% and less than or equal to about 20% of p1.

As described above, the acoustic wave device according to the first example embodiment includes the piezoelectric layer 2 including the first main surface 2a and the second main surface 2b opposite to the first main surface 2a and located in the first direction relative to the first main surface 2a, and the IDT electrode including the first electrode including electrode fingers extending in the second direction intersecting the first direction, and the second electrode including electrode fingers extending in the second direction and facing the electrode fingers of the first electrode in the third direction orthogonal or substantially orthogonal to the second direction. The IDT electrode includes the first group G1 of electrode fingers continuously arranged in the third direction, the second group G2 of electrode fingers continuously arranged in the third direction, and the third group G3 of electrode fingers continuously arranged in the third direction. The first group G1 of electrode fingers has the largest first width W1, the second group G2 of electrode fingers has the smallest second width W2, and the third group G3 of electrode fingers has the third width W3 that is larger than the second width W2. In the IDT electrode, the third group G3 of electrode fingers, the second group G2 of electrode fingers, the first group G1 of electrode fingers, the second group G2 of electrode fingers, and the third group G3 of electrode fingers are arranged in this order as viewed in the third direction.

With such a configuration, the plurality of electrode fingers 3 and 4 include electrode fingers having different widths W, thus making it possible to reduce or prevent spurious emissions. The piezoelectric layer 2 in the portion including the third group G3 of electrode fingers having relatively high strength is located on the outer side, in the X direction, of the piezoelectric layer 2 in the portion including the second group G2 of electrode fingers having weak strength. This makes it possible, even if heat or stress is applied, to reduce or prevent partial deflection of the piezoelectric layer 2 where the electrode fingers at the ends of the plurality of electrode fingers 3 and 4 in the X direction are located, and damage to the piezoelectric layer 2 due to cracks. The deflection of the piezoelectric layer 2 and destruction of the piezoelectric layer 2 can thus be reduced or prevented while reducing or preventing the spurious emissions.

The center-to-center distance p1 between adjacent electrode fingers in the first group G1 of electrode fingers, the center-to-center distance p2 between adjacent electrode fingers in the second group G2 of electrode fingers, and the center-to-center distance p3 between adjacent electrode fingers in the third group G3 of electrode fingers may be equal or substantially equal. In this case, again, the deflection of the piezoelectric layer 2 and the destruction of the piezoelectric layer 2 can be reduced or prevented while reducing or preventing the spurious emissions.

The center-to-center distance p1 between adjacent electrode fingers in the first group G1 of electrode fingers and the center-to-center distance p2 between adjacent electrode fingers in the second group G2 of electrode fingers may be different. In this case, again, the deflection of the piezoelectric layer 2 and the destruction of the piezoelectric layer 2 can be reduced or prevented while reducing or preventing the spurious emissions.

In an example embodiment, the thickness of the piezoelectric layer 2 is, for example, less than or equal to about 2p, where p is the center-to-center distance between adjacent electrode fingers 3 and 4. This makes it possible to effectively excite a bulk wave in the first-order thickness-shear mode.

In an example embodiment, for example, the piezoelectric layer 2 includes lithium niobate or lithium tantalate, for example. This makes it possible to provide an acoustic wave device capable of obtaining good resonance characteristics.

In an example embodiment, the Euler angles (φ, θ, ψ) of the lithium niobate or lithium tantalate of the piezoelectric layer 2 are within the range of the following Expression (1), Expression (2), or Expression (3). This makes it possible to sufficiently widen the fractional band width.

(0°±10°,0° to 20°, any ψ) Expression (1)

(0°±10°,20° to 80°,0° to 60°(1−(θ−50)²/900)^{1/2}) or (0°±10°,20° to 80°,[180°−60°(1−(θ−50)²/900)^{1/2}] to 180°) Expression (2)

(0°±10°,[180°−30°(1−(ψ−90)²/8100)^{1/2}] to 180°, any ψ) Expression (3)

In an example embodiment, the acoustic wave device is configured to be able to use bulk waves in thickness-shear mode. This increases a coupling coefficient, making it possible to provide an acoustic wave device capable of obtaining good resonance characteristics.

In an example embodiment, for example, d/p≤about 0.5, where d is the film thickness of the piezoelectric layer 2 and p is the center-to-center distance between the adjacent electrode fingers 3 and 4. This makes it possible to effectively excite the bulk wave in the first-order thickness-shear mode.

In another example embodiment, for example, d/p≤about 0.24. This makes it possible to more effectively excite the bulk wave in the first-order thickness-shear mode.

In an example embodiment, when a region where the adjacent first and second electrode fingers 3 and 4 overlap when viewed in the direction in which the adjacent first and second electrode fingers 3 and 4 face each other is an excitation region, MR≤about 1.75 (d/p)+0.075 is satisfied, where MR is the metallization ratio of the plurality of first electrode fingers 3 and second electrode fingers 4 to the excitation region. This makes it possible to reliably set the fractional band width to less than or equal to about 17%.

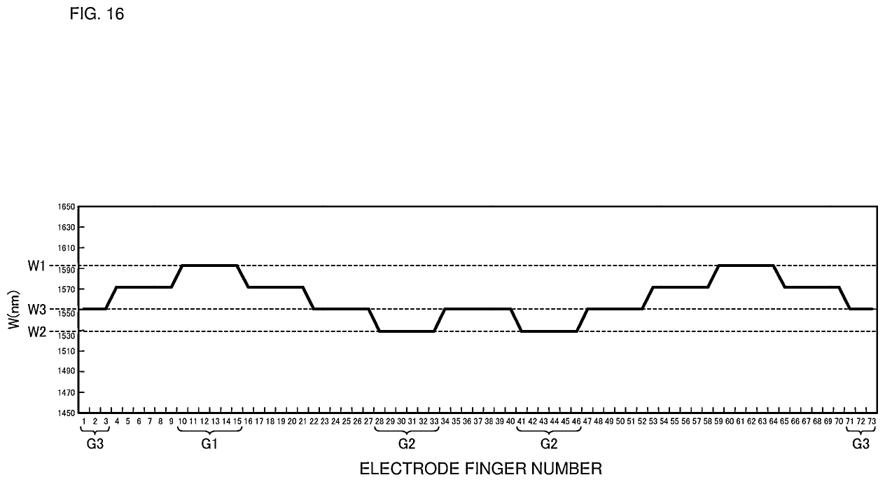

FIG. 16 is a graph illustrating the relationship between the position and width of the electrode fingers of the acoustic wave device according to a second example embodiment of the present invention. As illustrated in FIG. 16, the IDT electrode according to the second example embodiment is different from the first example embodiment in that the third group G3 of electrode fingers, the first group G1 of electrode fingers, the second group G2 of electrode fingers, the first group G1 of electrode fingers, and the third group G3 of electrode fingers are arranged in this order in ascending order of the electrode finger numbers. In other words, in the IDT electrode according to the second example embodiment, the first group G1 of electrode fingers having the largest width W are located on the outer side, in the X direction, of the second group G2 of electrode fingers having the smallest width W, and the third group G3 of electrode fingers having a width W smaller than that of the first group G1 of electrode fingers are located on the side of the first group G1 of electrode fingers, in the X direction, opposite to the side where the second group G2 of electrode fingers are located.

With such a configuration, in the second example embodiment, the plurality of electrode fingers 3 and 4 include electrode fingers having different widths W, thus making it possible to reduce or prevent the spurious emissions. On the other hand, the strength of the piezoelectric layer 2 in the portion where the second group G2 of electrode fingers is located on the inside of the first group G1 of electrode fingers in the X direction is smaller than that of the piezoelectric layer 2 in the portion where the first group G1 of electrode fingers is located. However, the strength of the piezoelectric layer 2 in the portion where the third group G3 of electrode fingers is located on the outside of the first group G1 of electrode fingers in the X direction is also smaller than that of the piezoelectric layer 2 in the portion where the first group G1 of electrode fingers is located. This makes it possible, even if heat or stress is applied, to reduce or prevent partial deflection of the piezoelectric layer 2 where the plurality of electrode fingers 3 and 4 are located, or damage to the piezoelectric layer 2 due to cracks. The deflection of the piezoelectric layer 2 and destruction of the piezoelectric layer 2 can thus be reduced or prevented while reducing or preventing the spurious emissions.

In the example of FIG. 16, the IDT electrode includes two second groups G2. That is, there is a group of electrode fingers having a width W larger than the second width W2 between the two second groups G2 in the X direction. With such a configuration, the piezoelectric layer 2 in the portion with the electrode fingers between the two second groups G2 has higher strength than the piezoelectric layer 2 in the portion with the second group G2 of electrode fingers. This makes it possible, even if heat or stress is applied, to further reduce or prevent partial deflection of the piezoelectric layer 2 where the plurality of electrode fingers 3 and 4 are located, or damage to the piezoelectric layer 2 due to cracks.

The acoustic wave device according to the second example embodiment has been described above. The acoustic wave device according to the second example embodiment is, however, not limited to the acoustic wave device described with reference to FIG. 16, and may be an acoustic wave device according to a modification described below.

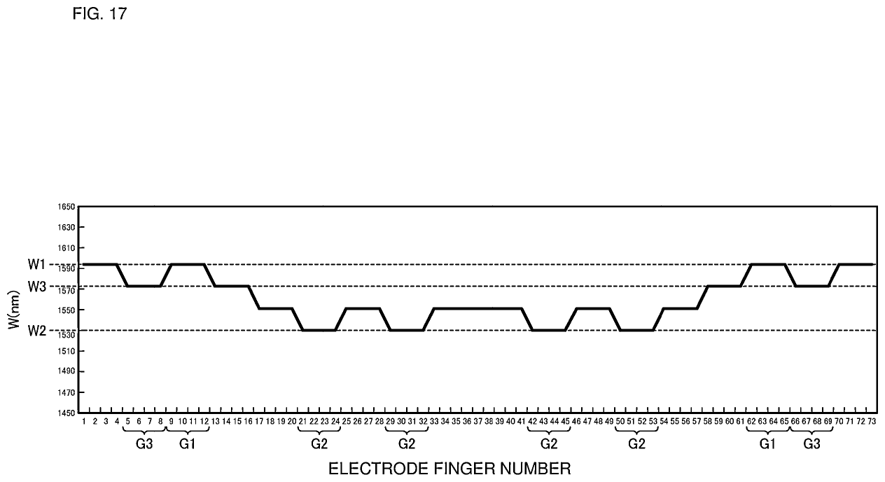

FIG. 17 is a graph illustrating the relationship between the position and width of electrode fingers in an acoustic wave device according to a modification of the second example embodiment. As illustrated in FIG. 17, in an IDT electrode according to the modification of the second example embodiment, a first group G1 of electrode fingers may be located on the outside of a third group G3 of electrode fingers in the X direction. That is, in the IDT electrode according to the modification of the second example embodiment, the first group G1 of electrode fingers, the third group G3 of electrode fingers, the first group G1 of electrode fingers, the second group G2 of electrode fingers, the first group G1 of electrode fingers, the third group G3 of electrode fingers, and the first group G1 of electrode fingers are arranged in this order in ascending order of the electrode finger numbers. In this case, the deflection of the piezoelectric layer 2 and the destruction of the piezoelectric layer 2 can be reduced or prevented while reducing or preventing spurious emissions.

In the example of FIG. 17, the IDT electrode includes four second groups G2. That is, there is a group of electrode fingers having a width W larger than the second width W2 between the four second groups G2 in the X direction. With such a configuration, the piezoelectric layer 2 in the portion with the electrode fingers between the four second groups G2 has higher strength than the piezoelectric layer 2 in the portion with the second group G2 of electrode fingers. This makes it possible, even if heat or stress is applied, to further reduce or prevent partial deflection of the piezoelectric layer 2 where the plurality of electrode fingers 3 and 4 are located, or damage to the piezoelectric layer 2 due to cracks.

As described above, the acoustic wave device according to the second example embodiment includes the piezoelectric layer 2 including the first main surface 2a and the second main surface 2b opposite to the first main surface 2a and located in the first direction relative to the first main surface 2a, and the IDT electrode including the first electrode including electrode fingers extending in the second direction intersecting the first direction, and the second electrode having electrode fingers extending in the second direction and facing the electrode fingers of the first electrode in the third direction orthogonal to the second direction. The IDT electrode includes the first group G1 of electrode fingers continuously arranged in the third direction, the second group G2 of electrode fingers continuously arranged in the third direction, and the third group G3 of electrode fingers continuously arranged in the third direction. The first group G1 of electrode fingers has the largest first width W1, the second group G2 of electrode fingers has the smallest second width W2, and the third group G3 of electrode fingers has the third width W3 that is smaller than the first width W1. In the IDT electrode, the third group G3 of electrode fingers, the first group G1 of electrode fingers, the second group G2 of electrode fingers, the first group G1 of electrode fingers, and the third group G3 of electrode fingers are arranged in this order as viewed in the third direction.

With such a configuration, the plurality of electrode fingers 3 and 4 include electrode fingers having different widths W, thus making it possible to reduce or prevent spurious emissions. The piezoelectric layer 2 in the portion including the first group G1 of electrode fingers having relatively high strength is located on the outer side, in the X direction, of the piezoelectric layer 2 in the portion including the second group G2 of electrode fingers having weak strength. Further on the outer side in the X direction, there is also the piezoelectric layer 2 in the portion including the third group G3 of electrode fingers having strength that is smaller than that of the piezoelectric layer 2 in the portion including the first group G1 and larger than that of the piezoelectric layer 2 in the portion including the second group G2. This makes it possible, even if heat or stress is applied, to reduce or prevent partial deflection of the piezoelectric layer 2 where the plurality of electrode fingers 3 and 4 are located, and damage to the piezoelectric layer 2 due to cracks. The deflection of the piezoelectric layer 2 and destruction of the piezoelectric layer 2 can thus be reduced or prevented while reducing or preventing the spurious emissions.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric layer including a first main surface and a second main surface opposite to the first main surface and located in a first direction relative to the first main surface; and
an IDT electrode including a first electrode including electrode fingers extending in a second direction intersecting the first direction, and a second electrode including electrode fingers extending in the second direction and facing the electrode fingers of the first electrode in a third direction orthogonal or substantially orthogonal to the second direction; wherein
the IDT electrode includes a first group of electrode fingers continuously arranged in the third direction, a second group of electrode fingers continuously arranged in the third direction, and a third group of electrode fingers continuously arranged in the third direction;
the first group of electrode fingers has a largest first width, the second group of electrode fingers has a smallest second width, and the third group of electrode fingers has a third width that is larger than the second width; and
the third group of electrode fingers, the second group of electrode fingers, the first group of electrode fingers, the second group of electrode fingers, and the third group of electrode fingers are arranged in this order as viewed in the third direction.

2. The acoustic wave device according to claim 1, wherein a center-to-center distance between adjacent electrode fingers in the first group of electrode fingers, a center-to-center distance between adjacent electrode fingers in the second group of electrode fingers, and a center-to-center distance between adjacent electrode fingers in the third group of electrode fingers are equal or substantially equal.

3. The acoustic wave device according to claim 1, wherein a center-to-center distance between adjacent electrode fingers in the first group of electrode fingers is different from a center-to-center distance between adjacent electrode fingers in the second group of electrode fingers.

4. The acoustic wave device according to claim 1, wherein a thickness of the piezoelectric layer is less than or equal to about 2p, where p is a center-to-center distance between adjacent electrode fingers.

5. The acoustic wave device according to claim 1, wherein the piezoelectric layer includes lithium niobate or lithium tantalate.

6. The acoustic wave device according to claim 1, wherein Euler angles (φ, θ, ψ) of lithium niobate or lithium tantalate of the piezoelectric layer are within a range of Expression (1), Expression (2), or Expression (3):
(0°±10°,0° to 20°, any ψ) Expression (1);
(0°±10°,20° to 80°,0° to 60°(1−(θ−50)²/900)^{1/2}) or (0°±10°,20° to 80°,[180°−60°(1−(θ−50)²/900)^{1/2}] to 180°) Expression (2); and
(0°±10°,[180°−30°(1−(ψ−90)²/8100)^{1/2}] to 180°, any ψ) Expression (3)

7. The acoustic wave device according to claim 4, wherein the acoustic wave device is structured to generate a bulk wave in a thickness-shear mode.

8. The acoustic wave device according to claim 1, wherein d/p≤about 0.5, where d is a thickness of the piezoelectric layer and p is a center-to-center distance between the electrode fingers adjacent to each other.

9. The acoustic wave device according to claim 8, wherein the d/p is less than or equal to about 0.24.

10. The acoustic wave device according to claim 1, wherein, when a region where adjacent electrode fingers overlap in a direction in which the adjacent electrode fingers face each other is an excitation region, MR≤about 1.75 (d/p)+0.075 is satisfied, where MR is a metallization ratio of a plurality of electrode fingers to the excitation region.

11. An acoustic wave device comprising:
a piezoelectric layer including a first main surface and a second main surface opposite to the first main surface and located in a first direction relative to the first main surface; and
an IDT electrode including a first electrode including electrode fingers extending in a second direction intersecting the first direction, and a second electrode including electrode fingers extending in the second direction and facing the electrode fingers of the first electrode in a third direction orthogonal to the second direction; wherein
the IDT electrode includes a first group of electrode fingers continuously arranged in the third direction, a second group of electrode fingers continuously arranged in the third direction, and a third group of electrode fingers continuously arranged in the third direction;
the first group of electrode fingers has a largest first width, the second group of electrode fingers has a smallest second width, and the third group of electrode fingers has a third width that is smaller than the first width; and
the third group of electrode fingers, the first group of electrode fingers, the second group of electrode fingers, the first group of electrode fingers, and the third group of electrode fingers are arranged in this order as viewed in the third direction.

12. The acoustic wave device according to claim 11, wherein a center-to-center distance between adjacent electrode fingers in the first group of electrode fingers, a center-to-center distance between adjacent electrode fingers in the second group of electrode fingers, and a center-to-center distance between adjacent electrode fingers in the third group of electrode fingers are equal or substantially equal.

13. The acoustic wave device according to claim 11, wherein a center-to-center distance between adjacent electrode fingers in the first group of electrode fingers is different from a center-to-center distance between adjacent electrode fingers in the second group of electrode fingers.

14. The acoustic wave device according to claim 11, wherein a thickness of the piezoelectric layer is less than or equal to about 2p, where p is a center-to-center distance between adjacent electrode fingers.

15. The acoustic wave device according to claim 11, wherein the piezoelectric layer includes lithium niobate or lithium tantalate.

16. The acoustic wave device according to claim 11, wherein Euler angles (φ, θ, ψ) of lithium niobate or lithium tantalate of the piezoelectric layer are within a range of Expression (1), Expression (2), or Expression (3):
(0°±10°,0° to 20°, any ψ) Expression (1);
(0°±10°,20° to 80°,0° to 60°(1−(θ−50)²/900)^{1/2}) or (0°±10°,20° to 80°,[180°−60°(1−(θ−50)²/900)^{1/2}] to 180°) Expression (2); and
(0°±10°,[180°−30°(1−(ψ−90)²/8100)^{1/2}] to 180°, any ψ) Expression (3)

17. The acoustic wave device according to claim 14, wherein the acoustic wave device is structured to generate a bulk wave in a thickness-shear mode.

18. The acoustic wave device according to claim 11, wherein d/p≤about 0.5, where d is a thickness of the piezoelectric layer and p is a center-to-center distance between the electrode fingers adjacent to each other.

19. The acoustic wave device according to claim 18, wherein the d/p is less than or equal to about 0.24.

20. The acoustic wave device according to claim 11, wherein, when a region where adjacent electrode fingers overlap in a direction in which the adjacent electrode fingers face each other is an excitation region, MR≤about 1.75 (d/p)+0.075 is satisfied, where MR is a metallization ratio of a plurality of electrode fingers to the excitation region.
